(19) United States
(12) Patent Application Publication
(10) Pub. No.: US 2025/0344438 A1
(43) Pub. Date: Nov. 6, 2025

(54) SEMICONDUCTOR DEVICES HAVING CONTACT FIELD PLATES AND METHODS FOR FORMING THE SAME

(71) Applicant: Taiwan Semiconductor Manufacturing Company, Ltd., Hsinchu (TW)

(72) Inventors: Cheng-Hsien Wu, Hsinchu (TW); Wen-Chih Chiang, Hsinchu (TW); Li-Hsin Chu, Taipei (TW); Cheng-Wei Wu, Taichung (TW)

(73) Assignee: Taiwan Semiconductor Manufacturing Company, Ltd., Hsinchu (TW)

(21) Appl. No.: 18/655,466

(22) Filed: May 6, 2024

(51) Int. Cl. H01L 29/78; H01L 23/528; H01L 29/40; H01L 29/66

(52) U.S. Cl. CPC H10D 30/655; H01L 23/5283; H10D 30/0285; H10D 64/112

(57) ABSTRACT

Semiconductor devices and methods for forming the same are provided. The methods include providing a substrate having source and drain structures separated by body and drift regions, a gate structure between the source and drain structures, an ILD layer over the source, drain, and gate structures, and a source contact coupled to the source structure. The methods include forming a first row of contact field plate (CFP) contacts in the ILD layer between the gate and drain structures, and forming a BEOL structure that is disposed on the ILD layer that includes a conductive metal layer coupled to the first row of CFP contacts and/or to the source structure. The method includes forming at least a second row of CFP contacts in the ILD layer between the gate structure and the drain structure, and/or electrically isolating the CFP contacts from the source structure.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically represents a cross-sectional view of a portion of a first semiconductor device at one stage in an integrated circuit manufacturing process in accordance with some embodiments;

FIG. 2 schematically represents a top, cross-sectional view of the first semiconductor device of FIG. 1 in accordance with some embodiments;

FIG. 3 schematically represents a cross-sectional view of a portion of a second semiconductor device at one stage in an integrated circuit manufacturing process in accordance with some embodiments;

FIG. 4 schematically represents a cross-sectional view of a portion of a third semiconductor device at one stage in an integrated circuit manufacturing process in accordance with some embodiments;

FIG. 5 schematically represents a cross-sectional view of a portion of a fourth semiconductor device at one stage in an integrated circuit manufacturing process in accordance with some embodiments;

FIG. 6 schematically represents a cross-sectional view of a portion of a fifth semiconductor device at one stage in an integrated circuit manufacturing process in accordance with some embodiments;

FIG. 7 schematically represents a cross-sectional view of a portion of a sixth semiconductor device at one stage in an integrated circuit manufacturing process in accordance with some embodiments;

FIG. 8 schematically represents a cross-sectional view of a portion of a seventh semiconductor device at one stage in an integrated circuit manufacturing process in accordance with some embodiments;

FIG. 9 schematically represents a cross-sectional view of a portion of an eighth semiconductor device at one stage in an integrated circuit manufacturing process in accordance with some embodiments;

FIG. 10 schematically represents a cross-sectional view of a portion of a nineth semiconductor device at one stage in an integrated circuit manufacturing process in accordance with some embodiments;

FIG. 11 schematically represents a top, cross-sectional view of a portion of a tenth semiconductor device at one stage in an integrated circuit manufacturing process in accordance with some embodiments;

FIG. 12 schematically represents a top, cross-sectional view of a portion of an eleventh semiconductor device at one stage in an integrated circuit manufacturing process in accordance with some embodiments;

FIG. 13 schematically represents a top, cross-sectional view of a portion of a twelfth semiconductor device at one stage in an integrated circuit manufacturing process in accordance with some embodiments;

FIG. 14 schematically represents a top, cross-sectional view of a portion of a thirteenth semiconductor device at one stage in an integrated circuit manufacturing process in accordance with some embodiments;

FIG. 15 schematically represents a top, cross-sectional view of a portion of a fourteenth semiconductor device at one stage in an integrated circuit manufacturing process in accordance with some embodiments;

FIGS. 16, 17, 18, and 19 schematically represent cross-sectional views of a fifteenth semiconductor device during various stages of a first exemplary method in accordance with some embodiments;

FIGS. 20, 21, 22, and 23 schematically represent cross-sectional views of a sixteenth semiconductor device during various stages of second exemplary method in accordance with some embodiments;

FIG. 24 is a flowchart illustrating a third exemplary method for forming a semiconductor device in accordance with some embodiments; and

FIG. 25 schematically represents a top, cross-sectional view of a portion of a seventeenth semiconductor device at one stage in an integrated circuit manufacturing process in accordance with some embodiments;

FIG. 26 schematically represents a top, cross-sectional view of a portion of an eighteenth semiconductor device at one stage in an integrated circuit manufacturing process in accordance with some embodiments; and

FIG. 27 schematically represents a top, cross-sectional view of a portion of a nineteenth semiconductor device at one stage in an integrated circuit manufacturing process in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

High voltage transistor devices are often constructed to have field plates. Field plates are conductive elements, which are placed over a channel region to enhance the performance of a high voltage transistor device by manipulating electric fields (e.g., reducing peak electric fields) generated by a gate electrode. By manipulating the electric field generated by the gate electrode, the high voltage transistor device can achieve higher breakdown voltages. For example, LDMOS (laterally diffused metal oxide semiconductor) transistor devices often comprise field plates that extend from a channel region to an adjacent drift region disposed between the channel region and a drain structure.

Field plates can be formed in a number of different ways. For example, a plurality of aligned contact field plate electrodes may be electrically coupled with a common source electrode by a conductive material. However, this arrangement may lead to linear drain current (I_{dlin}) degradation which may reduce efficiency of the contact field plate device in various applications, such as for buck converter applications. Linear drain current (I_{dlin}) is the measured drain current when a device is biased in a linear region.

Presented herein are embodiments of semiconductor structures and of methods for forming semiconductor structures with reduced linear drain current (I_{dlin}) degradation associated with field plate structures thereof. In various embodiments, the semiconductor structures include additional contact field plate electrodes and/or include contact field plate electrodes that are not electrically coupled to a source electrode.

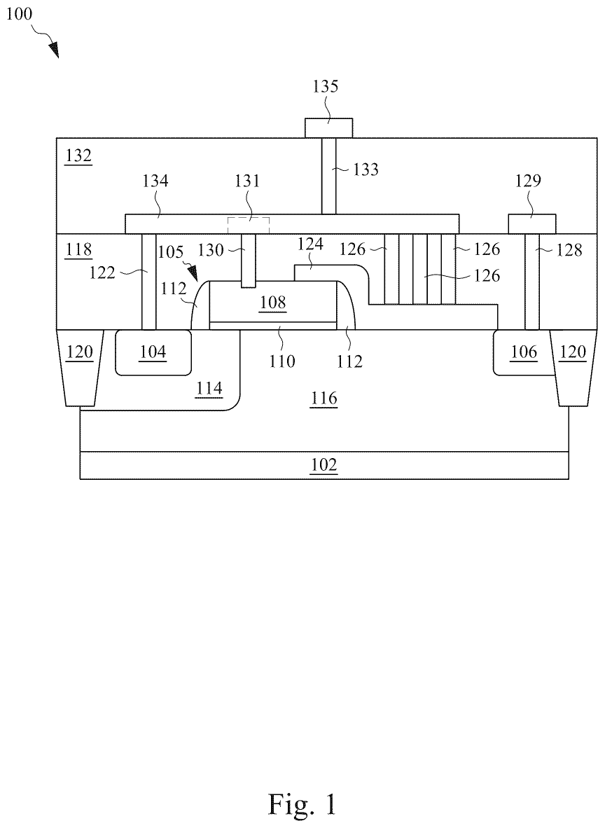

FIG. 1 illustrates a cross-sectional view of some embodiments of a semiconductor device comprising a laterally diffused MOSFET (LDMOS) device 100 having multiple rows of contact field plate (CFP) contacts 126. The semiconductor device is presented at one stage in an integrated circuit manufacturing process. Shown is a portion of the semiconductor device having electrical circuitry formed in and/or upon a substrate 102. The substrate 102 may be one of a variety of types of semiconductor substrates commonly employed in semiconductor integrated circuit fabrication, and integrated circuits may be formed therein and/or thereupon. The semiconductor substrate may be of any construction comprising semiconductor materials, including but not limited to, bulk silicon, a semiconductor wafer, a silicon-on-insulator (SOI) substrate, or a silicon germanium substrate. Other semiconductor materials, including group III, group IV, and/or group V semiconductors, can be used.

The LDMOS device 100 comprises a source region or structure 104 and a drain region or structure 106 disposed within the semiconductor substrate 102. The semiconductor substrate 102 may have a first doping type, while the source structure 104 and the drain structure 106 may comprise highly doped regions having a second doping type that may be different than the first doping type. In some embodiments, the first doping type may be p-type and the second doping type may be n-type. In other embodiments, the first doping type may be n-type and the second doping type may be p-type.

Various electrical components may be formed over the substrate 102. Examples of the electrical components may include active devices, such as transistors and diodes, and passive devices, such as capacitors, inductors, and resistors. The substrate 102 may include functional regions isolated by isolation features, such as shallow trench isolations (STis; e.g., STIs 120) features, that may include microelectronic elements formed in and/or upon the substrate 102. Examples of the types of microelectronic elements that may be formed in the substrate 102 include, but are not limited to, transistors such as metal oxide semiconductor field effect transistors (MOSFETs), complementary metal oxide semiconductor (CMOS) transistors, bipolar junction transistors (BJTs), high voltage transistors, high frequency transistors, p-channel and/or n-channel field effect transistors (PFETs/NFETs), resistors, diodes, capacitors, inductors, fuses, and/or other suitable elements. Various processes are performed to form the various microelectronic elements, including but not limited to one or more of deposition, etching, implantation, photolithography, annealing, and other suitable processes. The microelectronic elements are interconnected to form the integrated circuit device, which may comprise one or more of a logic device, memory device (e.g., SRAM), radio frequency (RF) device, input/output (I/O) device, system-on-chip (SoC) device, and other suitable types of devices.

The source structure 104 is disposed within a body region 114. The body region 114 has the first doping type with a doping concentration that is higher than that of the semiconductor substrate 102. For example, the semiconductor substrate 102 may have a doping concentration that is in a range of between approximately 10¹⁴ cm⁻³ and approximately 10¹⁶ cm⁻³, while the body region 114 may have a doping concentration that is in a range of between approximately 10¹⁶ cm⁻³ and approximately 10¹⁸ cm⁻³.

The drain structure 106 is disposed within a drift region 116 (e.g., n-well or p-well) that is arranged within the semiconductor substrate 102 at a position laterally abutting the body region 114. The drift region 116 comprises a second doping type having a relatively low doping concentration, which provides for a higher resistance when the LDMOS device 100 is operated at a high voltage. In some embodiments, the drift region 116 may have a doping concentration that is in a range of between approximately 10¹⁵ cm⁻³ and approximately 10¹⁷ cm⁻³.

A gate structure 105 is disposed over the semiconductor substrate 102 at a position that is laterally arranged between the source structure 104 and the drain structure 106. In some embodiments, the gate structure 105 may laterally extend from over the body region 114 to a position overlying a portion of the drift region 116. The gate structure 105 includes a gate electrode 108 that is separated from the semiconductor substrate 102 by a gate dielectric layer 110. In some embodiments, the gate dielectric layer 110 may comprise silicon dioxide (SiO₂) or a high-k gate dielectric material and the gate electrode 108 may comprise polysilicon or a metal gate material (e.g., aluminum). In some embodiments, the gate structure 105 may also comprise sidewall spacers 112 disposed on opposing sides of the gate electrode 108. In various embodiments, the sidewall spacers 112 may comprise a nitride based sidewall spacer (e.g., comprising SiN) or an oxide-based sidewall spacer (e.g., SiO₂, SiOC, etc.).

One or more dielectric layers 124 are disposed over the gate electrode 108 and the drift region 116 that define a reduced pinch-off. In some embodiments, the one or more dielectric layers 124 continuously extend from over a portion of the gate electrode 108 to over a portion of the drift region 116. In some embodiments, the one or more dielectric layers 124 may be conformally disposed onto the drift region 116, the gate electrode 108, and the sidewall spacers 112.

An inter-level dielectric (ILD) layer 118 may be disposed over the semiconductor substrate 102 and/or the various electrical components, and contacts (e.g., plugs) may be formed in the ILD layer 118 for providing electrical connections between other circuitry/elements. The formation operations of the contacts can include forming openings in the inter-layer dielectric layer ILD, filling the openings with conductive materials, and performing a planarization such as a chemical mechanical planarization (CMP) process. In some embodiments, the contacts can include tungsten (W), but other suitable conductive material such as silver (Ag), aluminum (Al), copper (Cu), AlCu, or the like may be used. One or more conductive metal structures may be disposed within the ILD layer 118. In some embodiments, the one or more conductive metal structures may comprise a plurality of contacts configured to provide for a vertical connection between the source structure 104, the drain structure 106, or the gate electrode 108 and one or more metal layers disposed within, for example, a first inter-metal dielectric (IMD) layer 132 overlying the ILD layer 118.

The plurality of contacts may comprise a source contact 122 coupled to the source structure 104, a drain contact 128 coupled to the drain structure 106, a gate contact 130 coupled to the gate electrode 108, and two or more rows of the CFP contacts 126 coupled to the one or more dielectric layers 124. In some embodiments, the plurality of contacts may comprise the same metal material. For example, the plurality of contacts may comprise one or more of tungsten (W), tantalum-nitride (TaN), titanium (Ti), titanium-nitride (TiN), aluminum copper (AlCu), copper (Cu), and/or other similar conductive materials. In some embodiments, the ILD layer 118 may comprise a dielectric material having a relatively low dielectric constant (e.g., less than or equal to approximately 3.9), which provides for electrical isolation between the plurality of contacts and/or the CFP contacts 126. In some embodiments, the ILD layer 118 may comprise an ultra-low k dielectric material or a low-k dielectric material (e.g., SiCO). The rows of CFP contacts 126 may be electrically coupled to the source contact 122 through a metal layer 134. In some embodiments, the metal layer 134 may be coupled to an additional metal layer 135 by a via 133 in the first IMD layer 132.

Upon receiving a bias voltage, the gate electrode 108 is configured to generate an electric field that controls the movement of charge carriers within a channel region (e.g., within the body region 114) laterally disposed between the source structure 104 and the drain structure 106. For example, during operation, a gate-source voltage (V_{GS}) can be selectively applied to the gate electrode 108 relative to the source structure 104, forming a conductive channel in the channel region. While V_{GS} is applied to form the conductive channel, a drain to source voltage (V_{DS}) is applied to the drain structure 106 relative to the source structure 104 to move charge carriers between the source structure 104 and the drain structure 106.

During operation, the CFP contacts 126 are configured to act upon the electric field generated by the gate electrode 108. The CFP contacts 126 may be configured to change a distribution of the electric field generated by the gate electrode 108 in the drift region 116, which enhances the internal electric field of the drift region 116 and increases the drift doping concentration of the drift region 116, thereby enhancing the breakdown voltage capability of the LDMOS device 100.

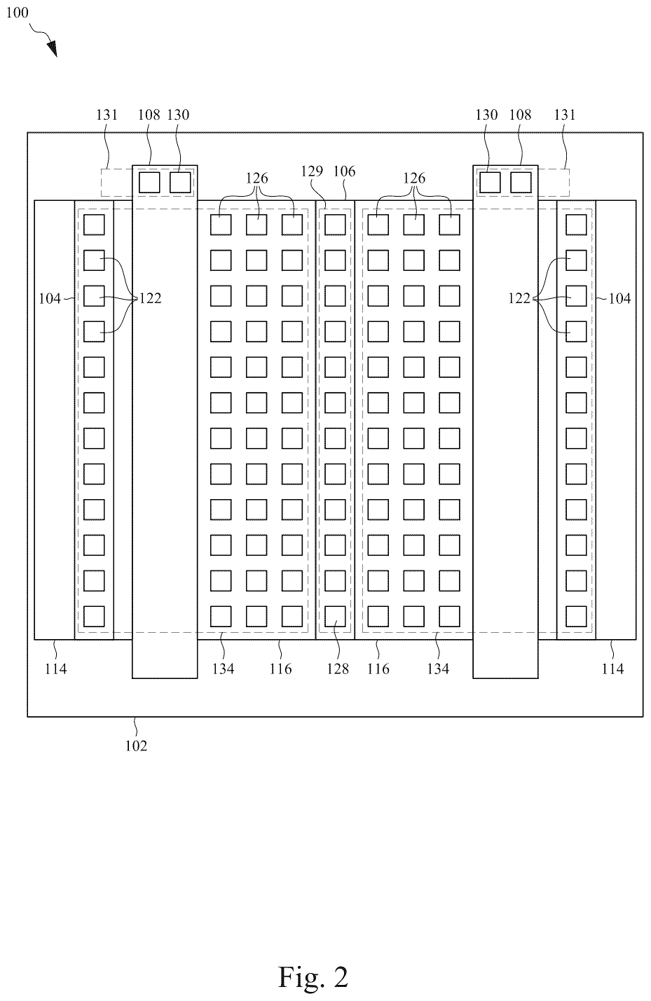

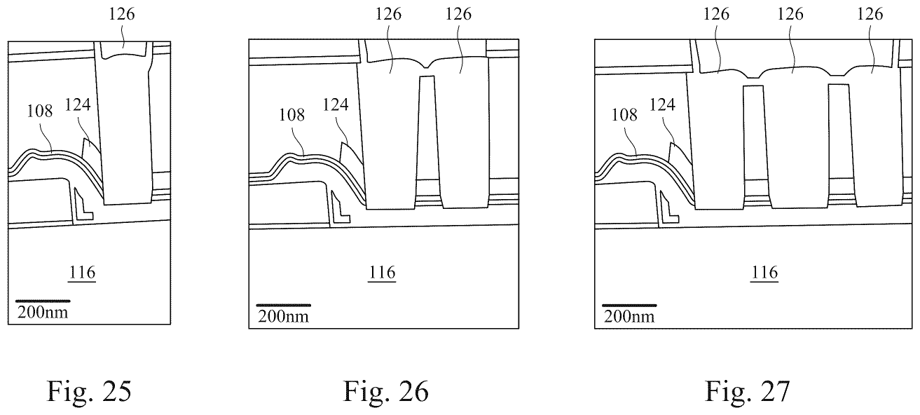

In the example of FIG. 1, the LDMOS device 100 includes three rows of CFP contacts 126. FIG. 2 illustrates a top, cross-sectional view of the LDMOS device 100 showing the three rows of the CFP contacts 126 between the drain contact 128 and the gate contact 130. Alternatively, the LDMOS device 100 may include two rows or more than three rows of CFP contacts 126. For example, FIGS. 25, 26, and 27 present examples of LDMOS devices having one, two, and three CFP contacts 126, respectively. In this example, the three rows are each aligned parallel to the source structure 104, and the CFP contacts 126 in each row are laterally aligned with CFP contacts 126 in the other rows. Alternatively, the semiconductor device may include rows of the CFP contacts 126 that are not aligned and/or that include CFP contacts 126 that are laterally offset from the CFP contacts 126 of other rows. By providing more than one row of the CFP contacts 126, the linear drain current (I_{dlin}) degradation may be reduced and the efficiency of the LDMOS device 100 may be promoted.

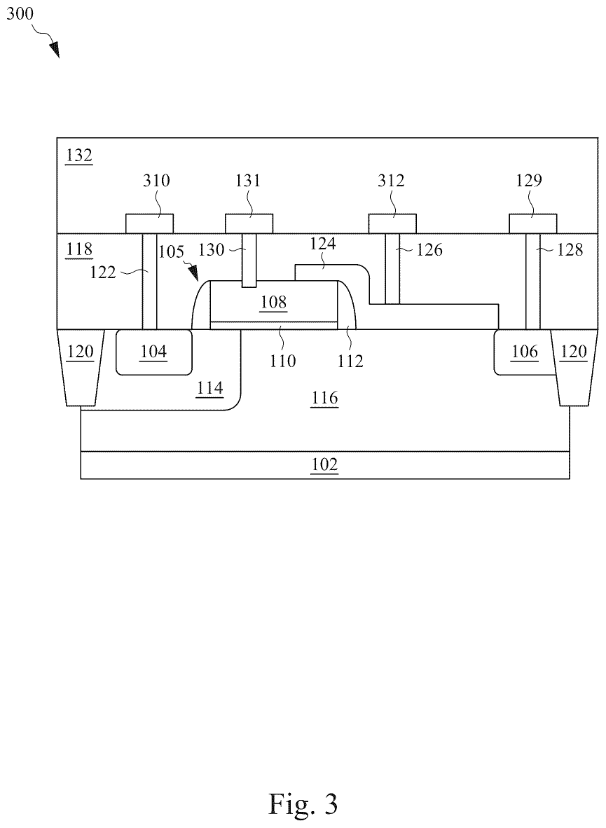

FIG. 3 illustrates a cross-sectional view of some embodiments of a semiconductor device comprising a laterally diffused MOSFET (LDMOS) device 300 having a single row of the CFP contacts 126. In some embodiments, the LDMOS device 300 may have more than one row of the CFP contacts 126, such as two, three, or more rows. In this embodiment, the CFP contacts 126 are electrically isolated from the source contact 122. That is, the CFP contacts 126 and the source contact 122 are not coupled by the metal layer 134 as in the embodiment of FIGS. 1 and 2. Instead, the source contact 122 and the CFP contacts 126 are coupled to separate metal layers 310 and 312, respectively. By isolating the CFP contacts 126 in this manner, the linear drain current (I_{dlin}) degradation may be reduced.

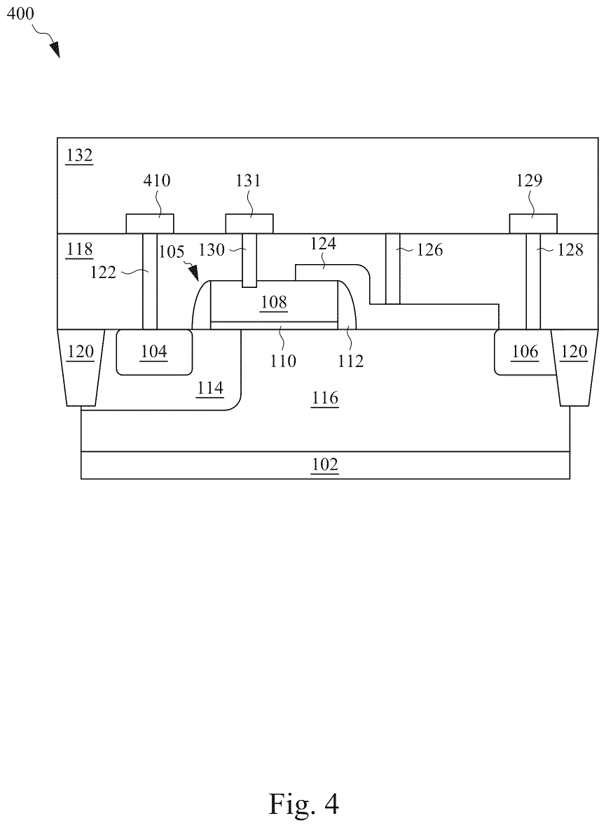

FIG. 4 illustrates a cross-sectional view of some embodiments of a semiconductor device comprising a laterally diffused MOSFET (LDMOS) device 400 having a single row of the CFP contacts 126. In some embodiments, the LDMOS device 400 may have more than one row of the CFP contacts 126, such as two, three, or more rows. In this embodiment, the CFP contacts 126 are floating, that is, the CFP contacts 126 are not connected to a metal layer in the first IMD layer 132 or otherwise electrically connected to, for example, a fixed voltage or ground. In other words, the CFP contacts 126 are electrically isolated. The source contact 122 is coupled to a metal layer 410. By isolating the CFP contacts 126 in this manner, the linear drain current (I_{dlin}) degradation may be reduced.

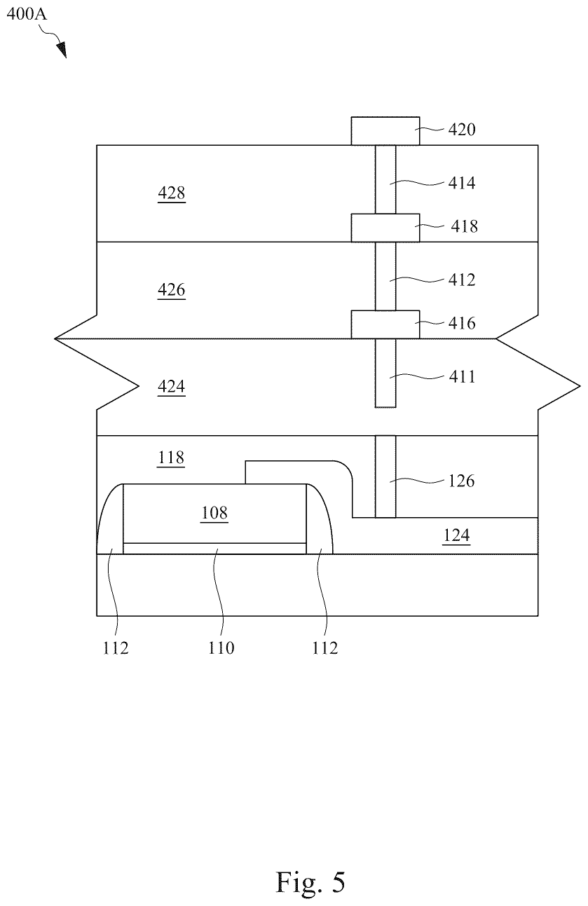

The concept illustrated in FIG. 4, that is, providing floating CFP contacts 126, may be alternatively implemented by providing a disconnect at other locations within the LDMOS device 400, that is, a feature that causes the CFP contacts 126 to be electrically isolated. FIGS. 5-10 illustrate isolated cross-sectional views showing alternative locations for the disconnect within a back end of the line (BEOL) structure of the semiconductor device. Various components of the semiconductor devices of FIGS. 5-10 are omitted for clarity. In these embodiments, the LDMOS device 400 may include any number of IMD layers (e.g., IMD1, IMD2, IMD3, . . . . IMDX) overlying the ILD layer 118. The IMD layer(s) may provide electrical insulation as well as structural support for the various features during many fabrication operations. The IMD layer(s) may include one or more of low-k dielectric materials, fluorine-doped silicon dioxide, organosilicates, carbon-doped oxides, porous silicon dioxide, organic polymeric dielectrics (e.g., polyimide, polynorbornenes, benzocyclobutene, and PTFE), silicon based polymeric dielectrics (e.g., hydrogen silsesquioxane, methylsilsesquioxane), and/or other commonly used materials. The dielectric constants (k value) of the low-k dielectric materials may be less than about 3.9.

Each of the IMD layers may include a corresponding metal layer (e.g., M1, M2, M3, . . . . MX) and via (Via1, Via2, Via3, . . . . ViaX) coupling the metal layer to an overlying IMBD layer. The metal layers and the vias may define an interconnect structure extending through the BEOL structure. A disconnect may be provided by omitting any one of these metal layers or vias to electrically isolate the CFP contacts 126. In some embodiments, the metal layers and/or the vias may each include a single layer or two or more layers. In some embodiments, metal layers and/or the vias may each include a fill material and a liner between the fill material and the dielectric material of the corresponding IMD layer. In some embodiments, the layers may include a liner formed of a noble metal or alloy thereof such as, but not limited to, rhenium (Re), rhodium (Rh), ruthenium (Ru), or alloys thereof. In some embodiments, the layers may include a fill material formed of copper (Cu), aluminum (Al), tungsten (W), silver (Ag), or alloys thereof.

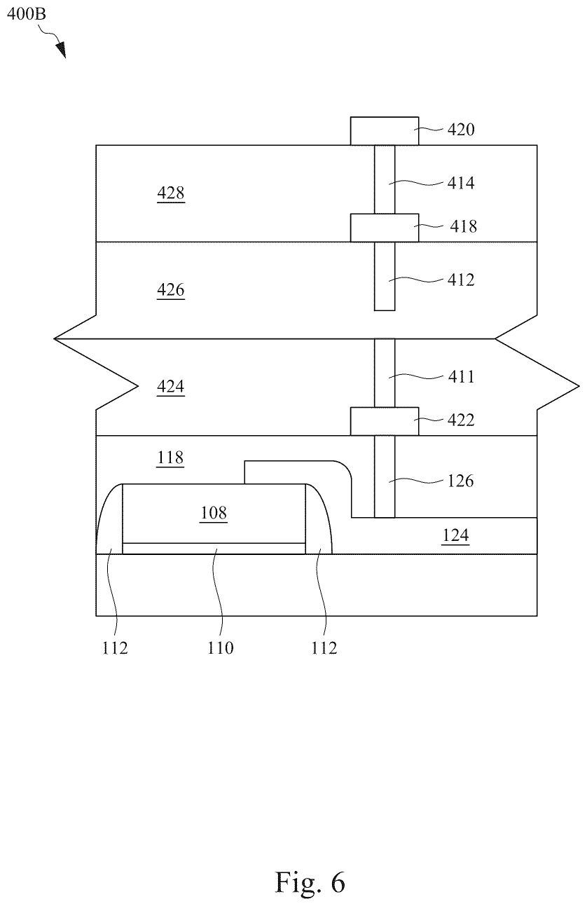

For example, FIG. 5 represents an LDMOS device 400A having a first IMD layer 424 overlying the ILD layer 118, a second IMD layer 426 overlying the first IMD layer 424, and a third IMD layer 428 overlying the second IMD layer 426. An interconnect structure is provided in the first, second, and third IMD layers 424, 426, and 428 that includes sequentially contacting first, second, and third vias 411, 412, and 414 and second and third metal layers 416 and 418, as well as a fourth metal layer 420 overlying the third IMD layer 428. A disconnect is provided in the first IMD layer 424, that is, a gap (defined by a portion of the first IMD layer 424) is provided between the CFP contacts 126 and the first via 411 (e.g., by omission of a first metal layer 422 shown in FIGS. 6-10) such that the CFP contacts 126 are not connected to the interconnect structure and therefore electrically isolated.

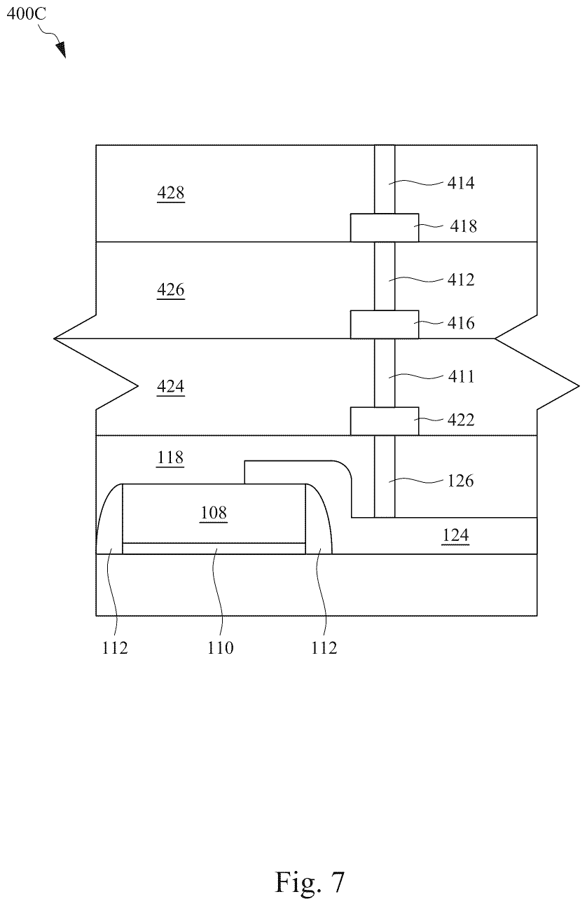

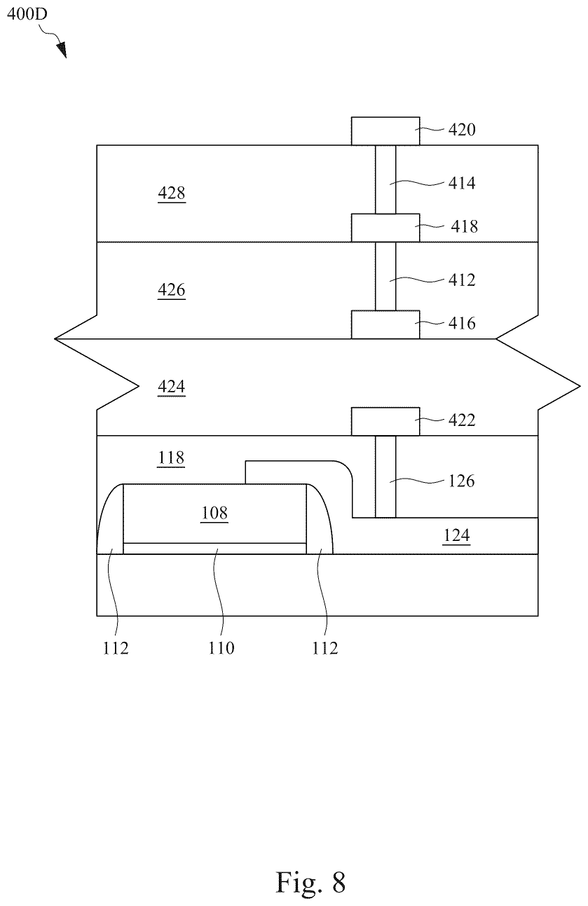

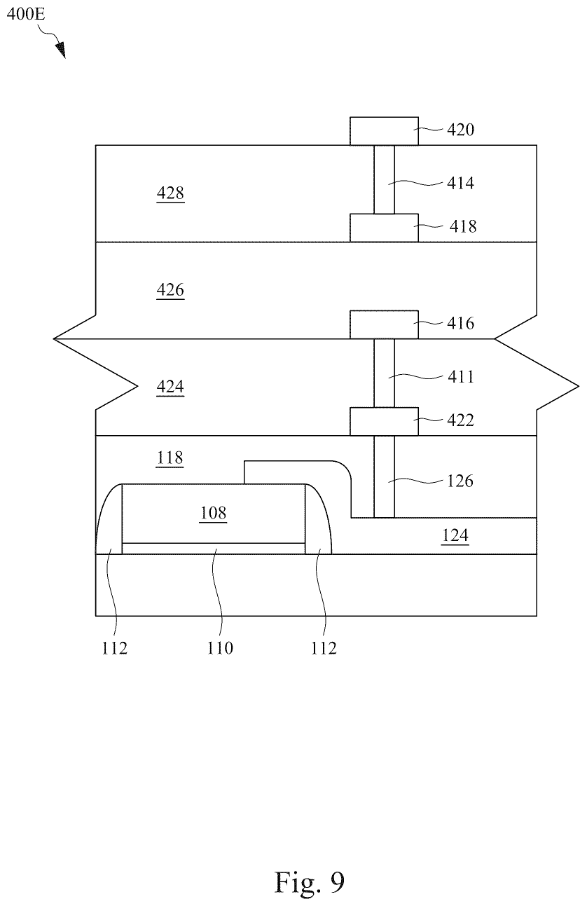

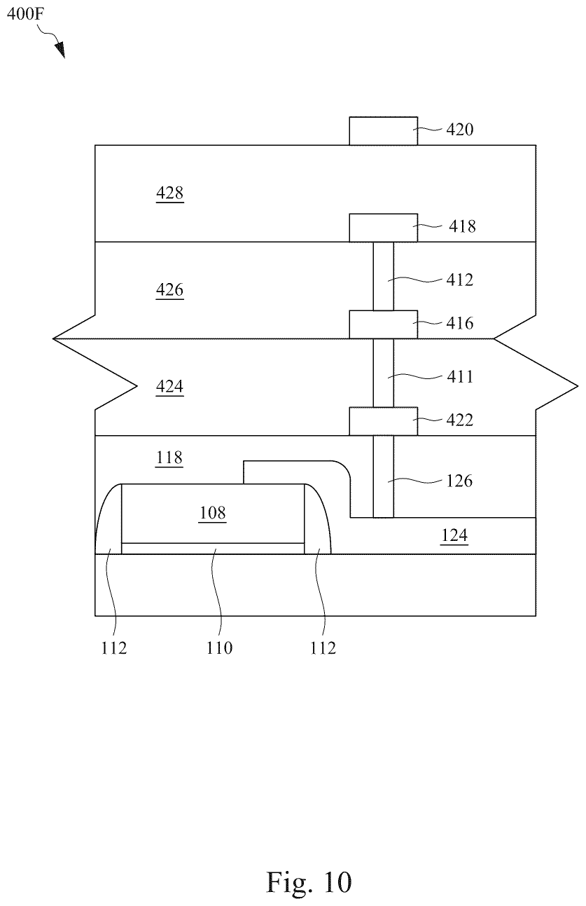

As another example, FIG. 6 represents an LDMOS device 400B having a disconnect in the second IMD layer 426 between the first and second vias 411 and 412 (e.g., by omission of the second metal layer 416). As another example, FIG. 7 represents an LDMOS device 400C having a disconnect above the third IMD layer 428 (e.g., by omission of the fourth metal layer 420). As another example, FIG. 8 represents an LDMOS device 400D having a disconnect in the first IMD layer 424 between the first and second metal layers 422 and 416 (e.g., by omission of the first via 411). As another example, FIG. 9 represents an LDMOS device 400E having a disconnect in the second IMD layer 426 between the second and third metal layers 416 and 418 (e.g., by omission of the second via 412). As another example, FIG. 10 represents an LDMOS device 400F having a disconnect in the third IMD layer 428 between the third and fourth metal layers 418 and 420 (e.g., by omission of the third via 414).

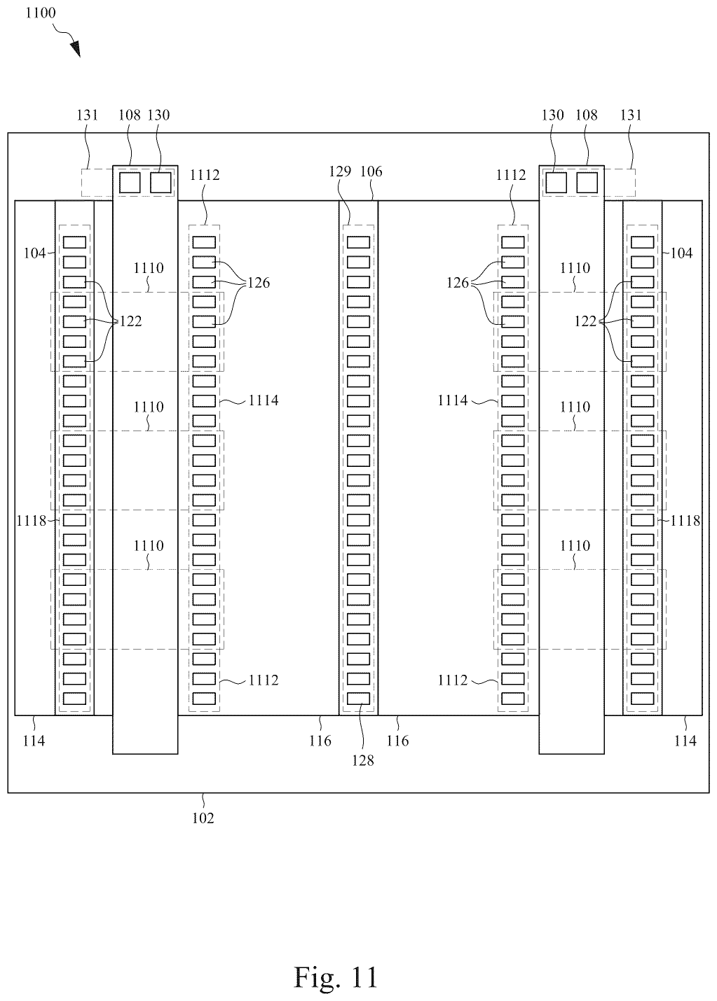

FIG. 11 illustrates a top, cross-sectional view of some embodiments of a semiconductor device comprising a laterally diffused MOSFET (LDMOS) device 1100 having a single row of the CFP contacts 126. In some embodiments, the LDMOS device 1100 may have more than one row of the CFP contacts 126, such as two, three, or more rows. In some embodiments, one or more of the CFP contacts 126 may be isolated from the source contact 122, for example, similar to the embodiment of FIG. 3. In some embodiments, one or more of the CFP contacts 126 may be floating, for example, similar to the embodiment of FIG. 4. In this embodiment, the source contacts 122 are connected to each other in a BEOL structure by a first metal layer 1118, some of the CFP contacts 126 are coupled to each other by a second metal layer 1114, and the first metal layer 1118 and the second metal layer 1114 are connected by spaced apart third metal layers 1110. Some others of the CFP contacts 126 are coupled to each other by fourth metal layers 1112. With this arrangement, the other CFP contacts 126 coupled by the fourth metal layers 1112 may be biased independently during off-state stress (i.e., not conducting current). In this manner, the linear drain current (I_{dlin}) degradation may be reduced. In this example, the other CFP contacts 126 coupled by the fourth metal layers 1112 are disposed adjacent to ends of the first row of the CFP contacts 126; however, this may not be required in other applications.

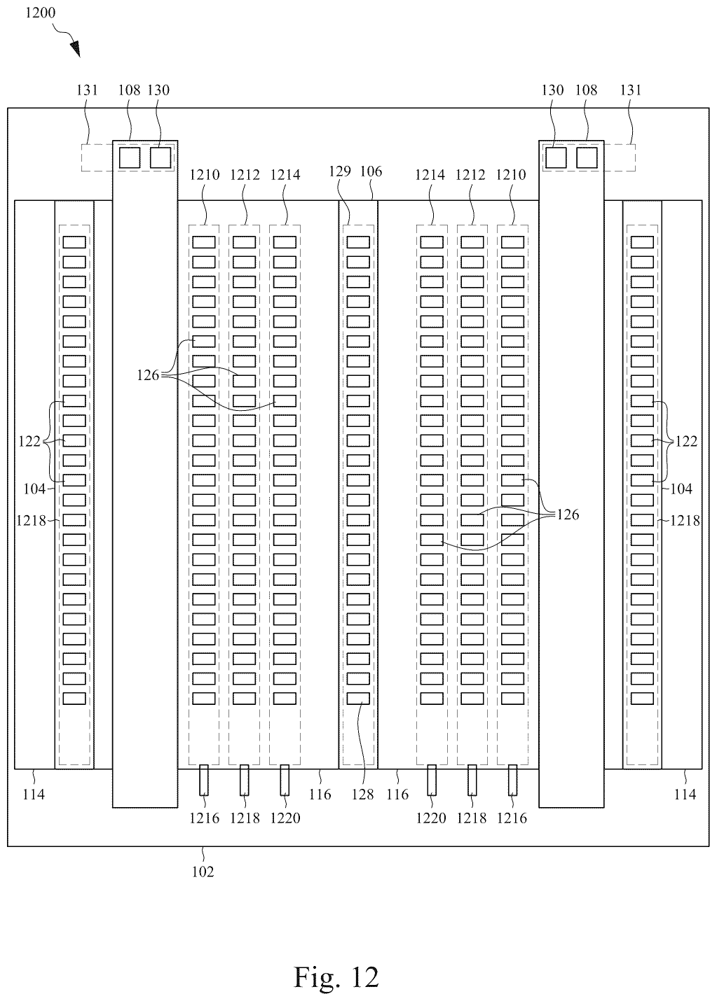

FIG. 12 illustrates a top, cross-sectional view of some embodiments of a semiconductor device comprising a laterally diffused MOSFET (LDMOS) device 1200 having three rows of the CFP contacts 126. In some embodiments, the LDMOS device 1200 may include two rows or more than three rows of CFP contacts 126. In this embodiment, the CFP contacts 126 of each row are coupled to each other in a BEOL structure but not to the CFP contacts 126 of other rows. That is, the CFP contacts 126 of a first row are all coupled by a first metal layer 1210, the CFP contacts 126 of a second row are all coupled by a second metal layer 1212, and the CFP contacts 126 of a third row are all coupled by a third metal layer 1214. Each of the rows of the CFP contacts 126 may be independently coupled to separate vias 1216, 1218, and 1220, respectively. With this arrangement, each of the rows of the CFP contacts 126 may be selectively provided with voltage or grounding. In this manner, the electric field of the drift region 116 may be adjusted to promote performance.

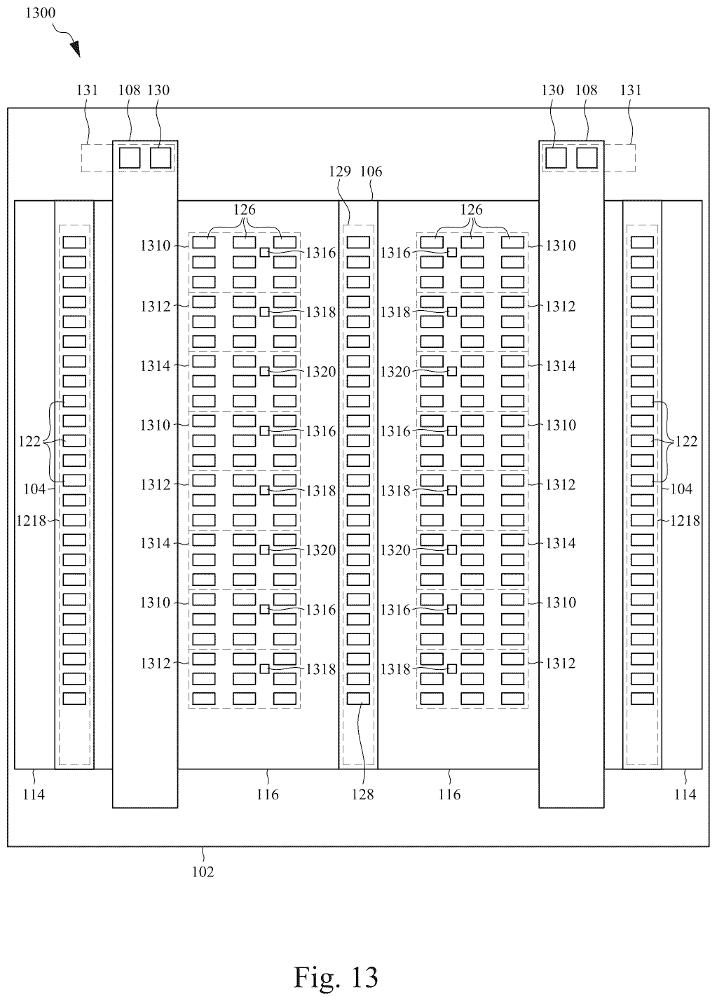

FIG. 13 illustrates a top, cross-sectional view of some embodiments of a semiconductor device comprising a laterally diffused MOSFET (LDMOS) device 1300 having three rows of the CFP contacts 126. In some embodiments, the LDMOS device 1300 may include two rows or more than three rows of CFP contacts 126. In this embodiment, the CFP contacts 126 of each row are organized into sets comprising some of the CFP contacts 126 from each row. The CFP contacts 126 of each set are coupled to each other in a BEOL structure but not to the CFP contacts 126 of other sets. For example, the CFP contacts 126 may be organized into a plurality of sets each comprising a 3×3 array of the CFP contacts 126, and the CFP contacts 126 within each of the sets may be coupled by a first metal layer 1310, a second metal layer 1312, or a third metal layer 1314. Each of the sets of the CFP contacts 126 may be independently coupled to one of separate vias 1316, 1318, and 1320. With this arrangement, each of the sets of the CFP contacts 126 may be selectively provided with voltage or grounding. In this manner, the electric field of the drift region 116 may be adjusted to promote performance.

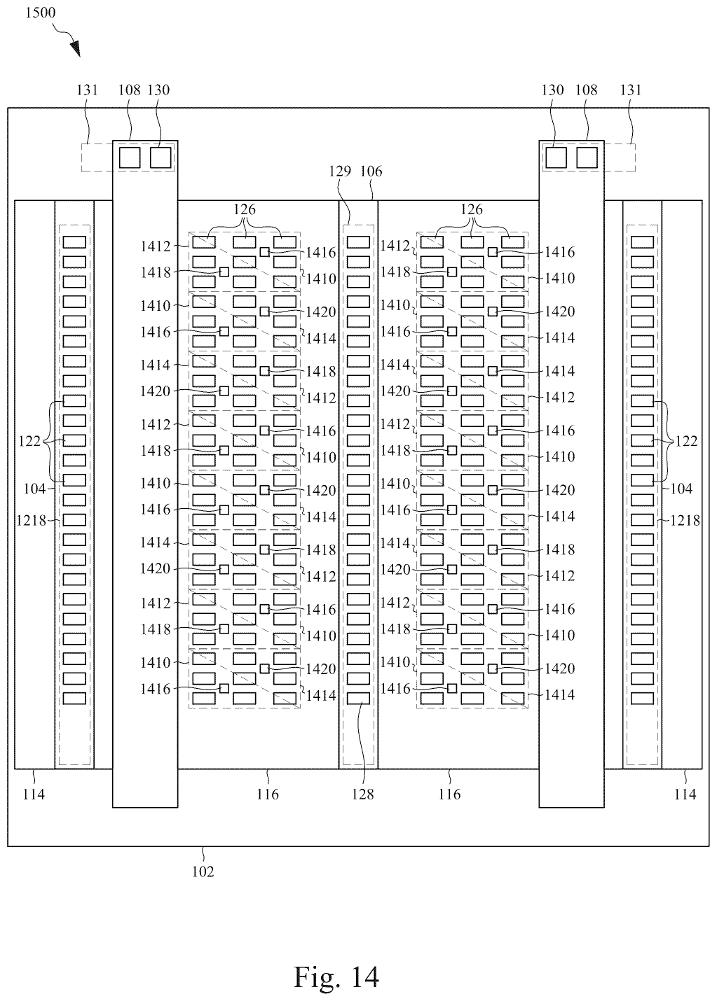

The rows of the CFP contacts 126 may be organized into sets having other quantities, shapes, etc. depending on the particular application. For example, FIG. 14 illustrates a top, cross-sectional view of some embodiments of a semiconductor device comprising a laterally diffused MOSFET (LDMOS) device 1400 having three rows of the CFP contacts 126. In this embodiment, the CFP contacts 126 may be organized into a plurality of sets each comprising, for example, six of the CFP contacts 126, and the CFP contacts 126 within each of the sets may be coupled by a first metal layer 1410, a second metal layer 1412, or a third metal layer 1414 each having a triangular shape from the perspective of FIG. 14. Each of the sets of the CFP contacts 126 may be independently coupled to one of the separate vias 1416, 1418, and 1420.

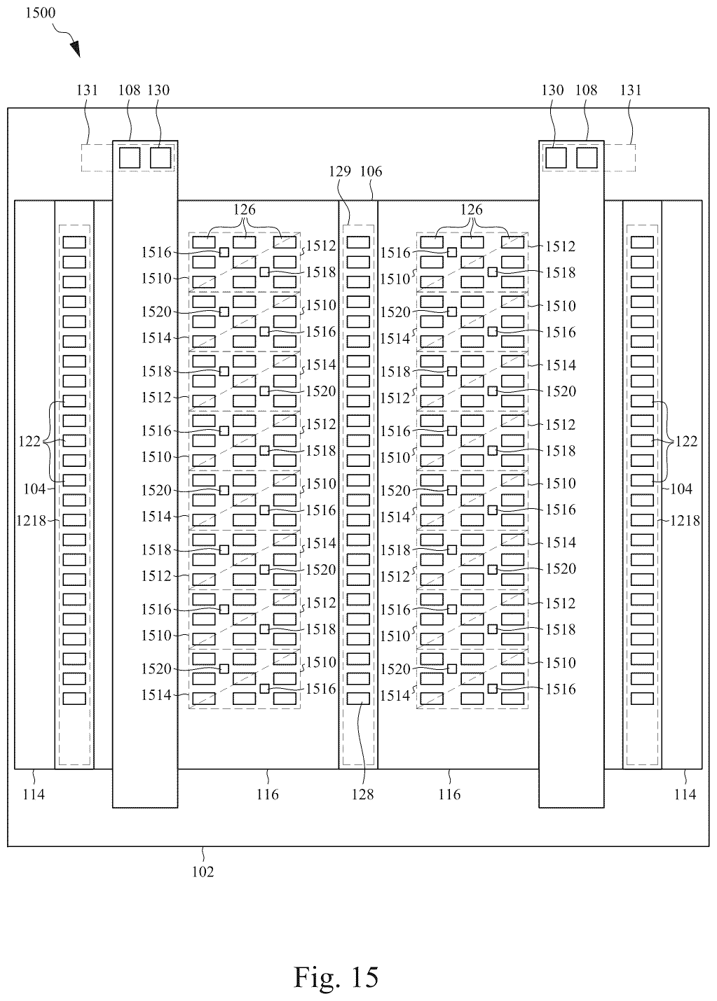

As another example, FIG. 15 illustrates a top, cross-sectional view of some embodiments of a semiconductor device comprising a laterally diffused MOSFET (LDMOS) device 1500 having three rows of the CFP contacts 126. The LDMOS device 1500 is substantially the same as the previously described LDMOS device 1400, but with different ones of the CFP contacts 126 in each of the sets. In this embodiment, the CFP contacts 126 within each of the sets are coupled by a first metal layer 1510, a second metal layer 1512, or a third metal layer 1514, and each of the sets of the CFP contacts 126 are independently coupled to one of the separate vias 1516, 1518, and 1520.

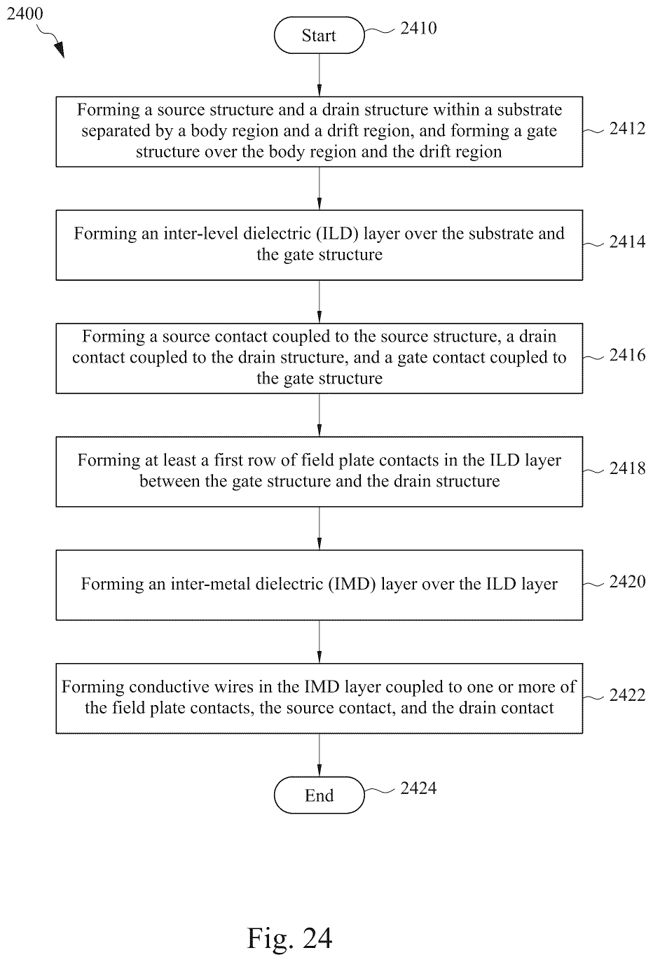

With reference now to FIG. 24 and with continued reference to FIGS. 1-15, a flowchart provides a method 2400 for forming a semiconductor device (e.g., a high voltage transistor device) having a field plate, in accordance with various examples. As can be appreciated in light of the disclosure, the order of operation within the method 2400 is not limited to the sequential execution as illustrated in FIG. 24, but may be performed in one or more varying orders as applicable and in accordance with the present disclosure.

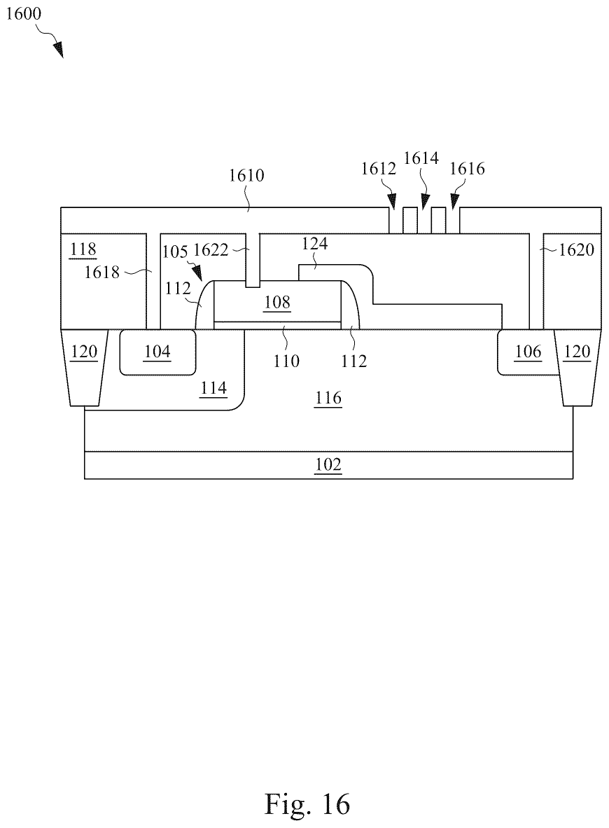

FIGS. 16-23 illustrate cross-sectional views of exemplary structures formed by the method 2400. Although the cross-sectional views shown in FIGS. 16-23 are described with reference to the method 2400, it will be appreciated that the structures shown in FIGS. 16-23 may be formed by other methods. It will also be appreciated that the method 2400 is not limited to the structures presented, and the method 2400 is also applicable to other structures. In other embodiments, some acts that are illustrated and/or described may be omitted in whole or in part.

The method 2400 may start at 2410. At 2412, the method 2400 may include forming a source structure and a drain structure within a substrate. In some embodiments, the source structure and the drain structure may be separated by a body region and a drift region. A gate structure may be formed over the body region and the drift region. In some embodiments, a method for forming the gate structure may include forming a gate dielectric layer over the substrate, and then forming a gate electrode over the gate dielectric layer. After forming the gate electrode, the source structure and the drain structure may be formed in the substrate by an implantation process. In some embodiments, other doped regions (e.g., the drift region and the body region) may be formed by one or more other implantation process(es) before forming the gate dielectric layer. In further embodiments, a portion of the doped regions may be formed before forming the gate dielectric layer, and/or a remaining portion of the other doped regions may be formed after forming the gate dielectric layer. One or more dielectric layers may be formed over the substrate and over at least a portion of the gate structure.

At 2414, the method 2400 may include forming an inter-level dielectric (ILD) layer over the substrate and the gate structure. The ILD layer may be formed over the one or more dielectric layers and the gate structure. In some embodiments, the ILD layer may be formed using a deposition process such as, for example, chemical vapor deposition (CVD), physical vapor deposition (PVD), some other suitable deposition process(es), or any combination of the foregoing.

At 2416, the method 2400 may include forming a source contact that is coupled to the source structure, forming a drain contact that is coupled to the drain structure, and forming gate contact that is coupled to the gate structure. At 2418, the method 2400 may include forming at least a first row of contact field plate (CFP) contacts in the ILD layer between the gate structure and the drain structure, and over the one or more dielectric layers. In some embodiments, the source contact, the drain contact, the gate contact, and the first row of field plate contacts may be formed by various processes, such as certain etching and photolithography processes.

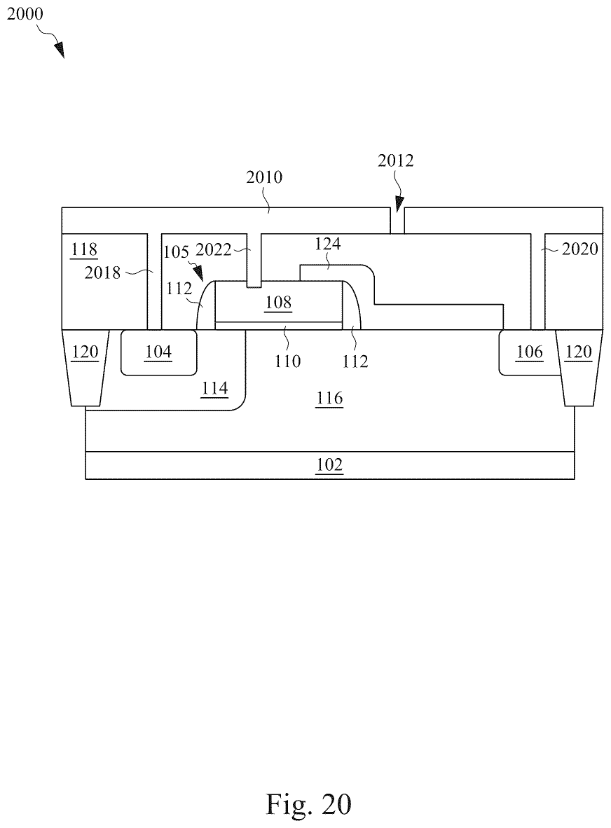

For example, FIG. 16 illustrates a structure 1600 that includes a first masking layer 1610 deposited over the ILD layer 118 with three openings 1612, 1614, and 1616 overlying the drift region 116. As another examples, FIG. 20 illustrates a structure 2000 that includes a first masking layer 2010 deposited over the ILD layer 118 with one opening 2012 overlying the drift region 116. In some embodiments, the first masking layers 1610 and 2010 may, for example, be or comprise a hard mask, a photoresist, or the like.

In some embodiments, etching processes may be performed on the structure 1600 of FIG. 16 and the structure 2000 of FIG. 20 to define openings in the ILD layer 118 corresponding to the openings 1612, 1614, 1616, and 2012. In some embodiments, the etching process(es) performed on the structure 1600 of FIG. 16 and the structure 2000 of FIG. 20 may be dry etch processes in which the ILD layer 118 is exposed to one or more etchants. In some embodiments, the one or more etchants may comprise dry etchants (e.g., having an etching chemistry comprising fluorine, chlorine, or the like). In some embodiments, the power of the etch process may be within a range of about 100 to 1,000 Watts (W). In some embodiments, after performing the etch process, a removal process is performed to remove the first masking layers 1610 and 2010 of FIGS. 16 and 20, respectively.

In these examples, source openings 1618 and 2018 overlie the source structure 104, drain openings 1620 and 2020 overlying the drain structure 106, and gate openings 1622 and 2022 overlie the gate electrode 108. These openings 1618, 2018, 1620, 2020, 1622, and 2022 may be formed prior to or subsequent to forming the openings 1612, 1614, 1616, and 2012. In some embodiments, the openings 1612, 1614, 1616, and 2012 may be formed with a second etch process such as a dry etch process in which the ILD layer 118 is exposed to one or more etchants.

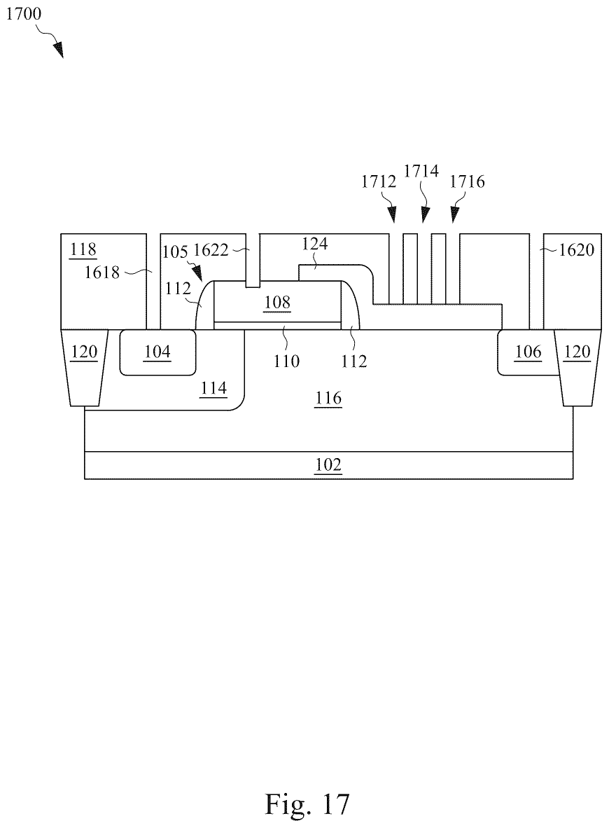

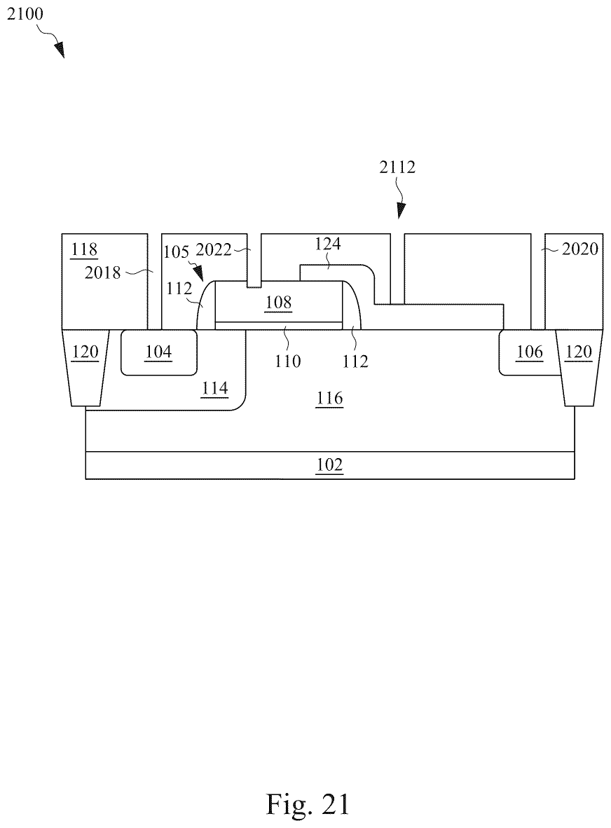

As examples, FIG. 17 illustrates a structure 1700 subsequent to a first etch process being performed on the structure 1600 of FIG. 16 according to the first masking layer (1610 of FIG. 16). The first etch process forms sidewalls and an upper surface of the ILD layer 118 that define at least three CFP openings 1712, 1714, and 1716. Similarly, FIG. 21 illustrates a structure 2100 subsequent to a first etch process being performed on the structure 2000 of FIG. 20 according to the first masking layer (2010 of FIG. 20). The first etch process forms sidewalls and an upper surface of the ILD layer 118 that define at least one CFP opening 2112.

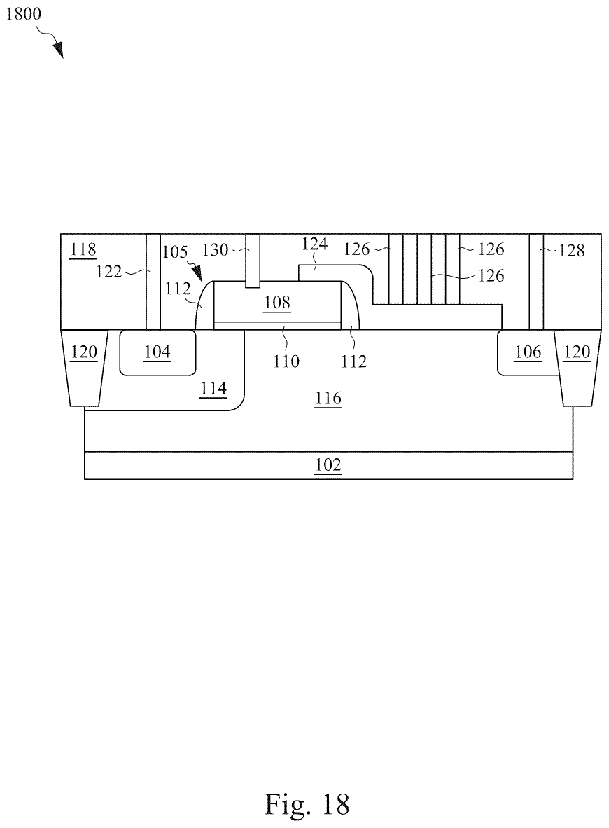

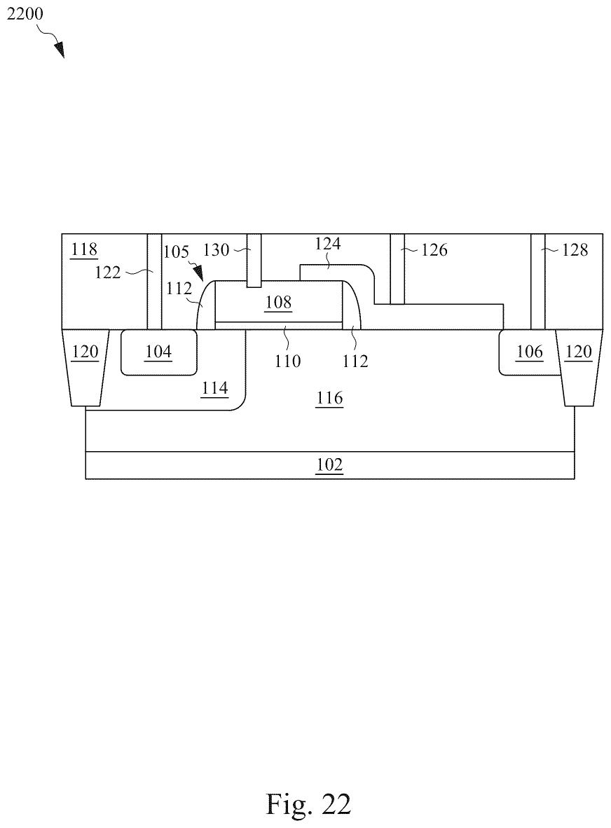

In some embodiments, the source opening 1618 of FIG. 17 and the source opening 2018 of FIG. 21 may be filled with one or more conductive materials to define the source contact 122, the drain opening 1620 of FIG. 17 and the drain opening 2018 of FIG. 21 may be filled with one or more conductive materials to define the drain contact 128, the gate opening 1622 of FIG. 17 and the gate opening 2022 of FIG. 21 may be filled with one or more conductive materials to define the gate contact 130, and the CFP openings 1712, 1714, and 1716 of FIG. 17 and the CFP opening 2112 of FIG. 21 may be filled with one or more conductive materials to define the CFP contact(s) 126. In some embodiments, the source contact 122, the drain contact 128, and the CFP contact(s) 126 may be formed by depositing a conductive material (e.g., aluminum, titanium, tantalum, tungsten, titanium nitride, tantalum nitride, or the like) over the ILD layer 118, thereby filling the openings 1618, 1620, 1622, 1712, 1714, and 1716 of FIG. 17 and the openings 2018, 2020, 2022, and 2112 of FIG. 21, and then performing a planarization process (e.g., a chemical mechanical planarization (CMP) process) on the conductive material until a top surface of the ILD layer 118 is reached. As examples, FIG. 18 illustrates a structure 1800 subsequent to formation of the source contact 122, the drain contact 128, and the CFP contacts 126 in the structure 1600 of FIG. 16, and FIG. 22 illustrates a structure 2200 subsequent to formation of the source contact 122, the drain contact 128, and the CFP contact 126 in the structure 2100 of FIG. 21.

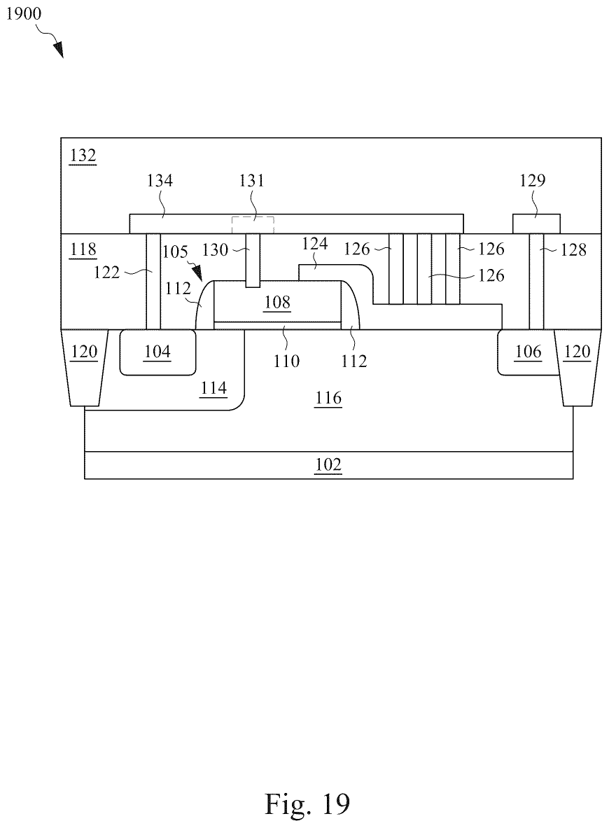

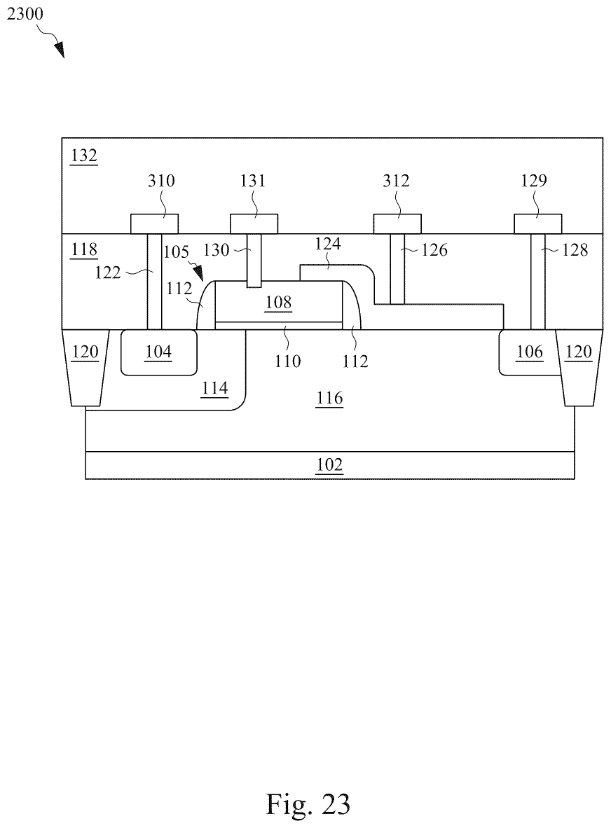

At 2420, the method 2400 may include forming an inter-metal dielectric (IMD) layer over the ILD layer. At 2422, the method 2400 may include forming conductive metal layers in the IMD layer that are coupled to one or more of the CFP contacts, the source contact, the drain contact, and the gate contact. In some embodiments, the metal layers may be formed by a damascene process (e.g., a single damascene process) and/or may comprise a material different from the source contact, the drain contact, and/or the CFP contacts. As examples, FIG. 19 illustrates a structure 1900 subsequent to formation of the first IMD layer 132 and metal layers 129, 131, and 134, and FIG. 23 illustrates a structure 2300 subsequent to formation of the first IMD layer 132 and metal layers 129, 131, 310, and 312. The method 2400 may end at 2424.

The present disclosure therefore provides semiconductor devices and methods for forming semiconductor devices that may significantly reduce I_{dlin} degradation after off-state stress in contact field plate LDMOS structures and thereby promote efficiency of such devices.

In accordance with an embodiment, a semiconductor device is provided that includes a body region and a drift region formed on a substrate, a source structure disposed within the body region and a drain structure disposed within the drift region, a gate structure including a gate electrode disposed over the body region and the drift region and a dielectric layer disposed over the gate electrode and the drift region, an inter-level dielectric (ILD) layer disposed over the substrate, at least first and second rows of contact field plate (CFP) contacts formed within the ILD layer above the dielectric layer, wherein each of the CFP contacts are configured to manipulate electric fields generated by the gate structure, and a back end of the line (BEOL) structure disposed on the ILD layer that includes at least one conductive metal layer coupling the first and second rows of CFP contacts to the source structure.

In accordance with another embodiment, a semiconductor device is provided that includes a body region and a drift region formed on a substrate, a source structure disposed within the body region and a drain structure disposed within the drift region, a gate structure including a gate electrode disposed over the body region and the drift region and a dielectric layer disposed over the gate electrode and the drift region, an inter-level dielectric (ILD) layer disposed over the substrate, and at least a first row of contact field plate (CFP) contacts formed within the ILD layer, wherein each of the CFP contacts are configured to manipulate electric fields generated by the gate structure, wherein at least some of the CFP contacts are electrically isolated from the source structure.

In accordance with yet another embodiment, a method is provided for fabricating a semiconductor device. The method includes providing a substrate having thereon a source structure and a drain structure separated by a body region and a drift region, a gate structure disposed between the source structure and the drain structure, an inter-level dielectric (ILD) layer disposed on the substrate and over the source structure, the drain structure, and the gate structure, and a source contact coupled to the source structure. The method includes forming at least a first row of contact field plate (CFP) contacts in the ILD layer between the gate structure and the drain structure, and forming a back end of the line (BEOL) structure that is disposed on the ILD layer that includes at least one conductive metal layer coupled to the first row of CFP contacts and/or to the source structure. The method includes forming at least a second row of CFP contacts in the ILD layer between the gate structure and the drain structure, and/or electrically isolating the CFP contacts from the source structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a body region and a drift region formed on a substrate;
a source structure disposed within the body region and a drain structure disposed within the drift region;
a gate structure including a gate electrode disposed over the body region and the drift region and a dielectric layer disposed over the gate electrode and the drift region;
an inter-level dielectric (ILD) layer disposed over the substrate;
at least first and second rows of contact field plate (CFP) contacts formed within the ILD layer above the dielectric layer, wherein each of the CFP contacts are configured to manipulate electric fields generated by the gate structure; and
a back end of the line (BEOL) structure disposed on the ILD layer that includes at least one conductive metal layer coupling the first and second rows of CFP contacts to the source structure.

2. The semiconductor device of claim 1, wherein each of the first and second rows of CFP contacts are aligned parallel to the source structure.

3. The semiconductor device of claim 1, wherein the BEOL structure is configured to provide for independently biasing at least a first set of the CFP contacts relative to a second set of the CFP contacts during off-state stress.

4. The semiconductor device of claim 3, wherein the first set of the CFP contacts includes some of the CFP contacts from both the first and second rows of CFP contacts.

5. The semiconductor device of claim 3, wherein the first set of the CFP contacts are disposed at an end of the first row of CFP contacts.

6. The semiconductor device of claim 1, wherein the BEOL structure includes at least a first conductive metal layer coupling the first row of CFP contacts to each other and at least a second conductive metal layer coupling the second row of CFP contacts to each other, wherein the BEOL structure is configured to selectively provide the first conductive metal layer and the second conductive metal layer with voltage or grounding independent of each other.

7. A semiconductor device, comprising:
a body region and a drift region formed on a substrate;
a source structure disposed within the body region and a drain structure disposed within the drift region;
a gate structure including a gate electrode disposed over the body region and the drift region and a dielectric layer disposed over the gate electrode and the drift region;
an inter-level dielectric (ILD) layer disposed over the substrate; and
at least a first row of contact field plate (CFP) contacts formed within the ILD layer, wherein each of the CFP contacts are configured to manipulate electric fields generated by the gate structure, wherein at least some of the CFP contacts are electrically isolated from the source structure.

8. The semiconductor device of claim 7, further comprising:
at least a second row of CFP contacts formed within the ILD layer; and
a back end of the line (BEOL) structure disposed on the ILD layer that includes at least a first conductive metal layer coupling the first row of CFP contacts to each other and at least a second conductive metal layer coupling the second row of CFP contacts to each other, wherein the BEOL structure is configured to selectively provide the first conductive metal layer and the second conductive metal layer with voltage or grounding independent of each other.

9. The semiconductor device of claim 7, further comprising:
at least a second row of the CFP contacts formed within the ILD layer; and
a back end of the line (BEOL) structure disposed on the ILD layer that includes at least a first conductive metal layer coupling a first set of the CFP contacts from both the first row and the second row to each other and at least a second conductive metal layer coupling a second set of the CFP contacts from both the first row and the second row to each other, wherein the BEOL structure is configured to selectively provide the first set and the second set with voltage or grounding independent of each other.

10. The semiconductor device of claim 7, further comprising:
a back end of the line (BEOL) structure disposed on the ILD layer that includes at least a first conductive metal layer coupling a first set of the CFP contacts to each other and at least a second conductive metal layer coupling a second set of the CFP contacts, wherein the BEOL structure is configured to selectively provide the first set and the second set with voltage or grounding independent of each other, wherein the first set of the CFP contacts are disposed at an end of the first row of CFP contacts and are electrically isolated from the source structure.

11. The semiconductor device of claim 7, further comprising a back end of the line (BEOL) structure disposed on the ILD layer wherein the BEOL structure is configured to provide for independently biasing at least a first set of the CFP contacts relative to a second set of the CFP contacts while the semiconductor device is in an off-state.

12. The semiconductor device of claim 7, further comprising a back end of the line (BEOL) structure disposed on the ILD layer that includes are least one conductive metal layer coupling the first row of CFP contacts to each other.

13. The semiconductor device of claim 12, wherein the BEOL structure includes an interconnect structure extending therethrough that is associated with the first row of CFP contacts, wherein the interconnect structure includes at least one disconnect therein that causes the CFP contacts to float.

14. A method for fabricating a semiconductor device, comprising:
providing a substrate having thereon a source structure and a drain structure separated by a body region and a drift region, a gate structure disposed between the source structure and the drain structure, an inter-level dielectric (ILD) layer disposed on the substrate and over the source structure, the drain structure, and the gate structure, and a source contact coupled to the source structure;
forming at least a first row of contact field plate (CFP) contacts in the ILD layer between the gate structure and the drain structure; and
forming a back end of the line (BEOL) structure that is disposed on the ILD layer that includes at least one conductive metal layer coupled to the first row of CFP contacts and/or to the source structure,
wherein the method includes forming at least a second row of CFP contacts in the ILD layer between the gate structure and the drain structure, and/or electrically isolating the CFP contacts from the source structure.

15. The method of claim 14, further comprising forming at least a first conductive metal layer in the BEOL structure coupling the first row of CFP contacts to each other and forming at least a second conductive metal layer in the BEOL structure coupling the second row of CFP contacts to each other, wherein forming the BEOL structure includes configuring the BEOL structure to selectively provide the first conductive metal layer and the second conductive metal layer with voltage or grounding independent of each other.

16. The method of claim 14, further comprising forming at least a first conductive metal layer in the BEOL structure coupling a first set of the CFP contacts from both the first row and the second row to each other and forming at least a second conductive metal layer in the BEOL structure coupling a second set of the CFP contacts from both the first row and the second row to each other, wherein forming the BEOL structure includes configuring the BEOL structure to selectively provide the first set and the second set with voltage or grounding independent of each other.

17. The method of claim 14, further comprising forming at least a first conductive metal layer in the BEOL structure coupling a first set of the CFP contacts to each other and at least a second conductive metal layer coupling a second set of the CFP contacts, wherein the BEOL structure is configured to selectively provide the first set and the second set with voltage or grounding independent of each other, wherein the first set of the CFP contacts are disposed at an end of the first row of CFP contacts and are electrically isolated from the source structure.

18. The method of claim 14, wherein forming the BEOL structure includes configuring the BEOL structure to provide for independently biasing at least a first set of the CFP contacts relative to a second set of the CFP contacts while the semiconductor device is in an off-state.

19. The method of claim 14, wherein forming the BEOL structure includes forming an interconnect structure extending through the BEOL structure that is associated with the first row of CFP contacts, wherein the interconnect structure includes at least one disconnect therein that causes the CFP contacts float.

20. The method of claim 14, wherein the method does not include forming the second row of CFP contacts in the ILD layer between the gate structure and the drain structure.
